(19) United States
(12) Patent Application Publication
(10) Pub. No.: US 2014/0000957 A1
(43) Pub. Date: Jan. 2, 2014

(54) Method for forming integrated component and formed integrated component

(71) Applicant: Perlos(Guangzhou) Electronic Components Co., Ltd., (US)

(72) Inventors: SeungYeob Lee, Guangzhou (CN); Brian Lin, Guangzhou (CN); Peter Jang, Guangzhou (CN)

(21) Appl. No.: 13/888,479

(22) Filed: May 7, 2013

(30) Foreign Application Priority Data
May 8, 2012 (CN) 2012101414166

(51) Int. Cl. H05K 13/00

(52) U.S. Cl. CPC H05K 13/00
USPC 174/535; 156/245

(57) ABSTRACT

The disclosure provides a method for forming an integrated component, which includes the following steps: bonding a transparent member and a substrate member together through an adhesive; placing the transparent member and the substrate member which are bonded together in a mould; and forming a housing member at a periphery of the transparent member and the substrate member which are bonded together, through an insert moulding technology, so that the housing member and the transparent member are jointed together tightly to form the integrated component. The disclosure also provides an integrated component formed by the above method. The integrated component formed by the method of the disclosure can better achieve a tight and stable connection between the transparent member and the housing member, achieve an interlocking and seamless connection between the transparent member and the housing member, and guarantee that the quality of the transparent member is not affected.

### TECHNICAL FIELD

The disclosure relates to the assembly technology of electronic products, and in particular to a method for forming an integrated component, and to an integrated component.

### BACKGROUND

When manufacturing electronic products, such as a cell phone, music players (MP3, MP4 and the like), tablet computer and the like, it is needed to mount a transparent display part in a shell. For example, display screen made of glass is mounted in shells of some cell phones. To implement the connection between the glass part and the shell, the related art mainly includes two ways. The first way is to drill a hole; as shown in FIG. 1, the first way specifically includes drilling a hole on a glass part 1 to fix the glass part 1 on a mould 2, and then mounting the glass part 1 into a formed shell (not shown) by operating a tool 2. Due to the existence of drill-hole 3 on the glass part 1, the intensity of the glass part 1 is affected, thus, the glass part 1 is easily broken during the operating process, and consequently the productivity is low. The second way is to adopt an absorption manner; as shown in FIG. 2, the second way specifically includes jointing the glass part 1 and the tool 2 together through an absorption part 4, and then mounting the glass part 1 into a formed shell (not shown) by operating the tool 2. Since the suction strength of the absorption part 4 is difficult to be controlled precisely, the position of the glass part 1 cannot be controlled precisely, thus, instability of operation is caused and production efficiency is affected. Besides the above defects, sliding is easily generated between the glass part and the shell for the joint surface between the glass part and the shell is a flat surface; thus, the stable and tight connection between the glass part and the shell is affected.

Therefore, it is needed to provide an effective method for jointing the glass part and the shell, so that a stable, tight and reliable connection is formed between the shell and the glass part, and the quality of the glass part is not affected.

### SUMMARY

The first purpose of the disclosure is to provide a method for forming an integrated component, so that a stable and tight connection is formed between a housing member and a transparent member.

The second purpose of the disclosure is to provide a method for forming an integrated component, so that an interlocking and seamless connection is formed between the housing member and the transparent member.

The third purpose of the disclosure is to provide a method for forming an integrated component, which can guarantee that the quality of the transparent member is not affected.

The fourth purpose of the disclosure is to provide an integrated component, which includes a transparent member and a housing member, wherein a stable and tight connection is formed between the transparent member and the housing member.

The fifth purpose of the disclosure is to provide an integrated component, which includes a transparent member and a housing member, wherein an interlocking and seamless connection is formed between the transparent member and the housing member.

According to one aspect of the disclosure, a method for forming an integrated component is provided, which includes the following steps: bonding a transparent member and a substrate member together through an adhesive; placing the transparent member and the substrate member which are bonded together in a mould; and forming a housing member at a periphery of the transparent member and the substrate member which are bonded together, through an insert moulding technology, so that the housing member and the transparent member are jointed together to form an integrated component.

Preferably, the transparent member may be glass.

Preferably, the substrate member may be a frame.

Preferably, the substrate member may be an insert moulding label foil.

Preferably, at least one connection feature may be located at an edge of the transparent member.

Preferably, the connection feature may be a concave portion formed on the edge of the transparent member through a cutting technology, or a concave portion located at the edge of the transparent member and integrally formed with the transparent member.

Preferably, the concave portion may be a ¼ arc formed in a height direction of the transparent member.

Preferably, the connection feature may be a concave portion located at the edge of the transparent member and integrally formed with the transparent member.

According to another aspect of the disclosure, an integrated component is provided, which includes: a transparent member, a substrate member and a housing member, wherein the transparent member and the substrate member are bonded together through an adhesive; the housing member is formed at a periphery of the transparent member and the substrate member which are bonded together, through an insert moulding technology, and is jointed with the transparent member and the substrate member.

Preferably, the transparent member may be glass.

Preferably, the substrate member may be a frame.

Preferably, the substrate member may be an insert moulding label foil.

Preferably, at least one connection feature may be located at an edge of the transparent member.

Preferably, the connection feature may be a concave portion formed on the edge of the transparent member through a cutting technology, or a concave portion located at the edge of the transparent member and integrally formed with the transparent member.

Preferably, the concave portion may be a ¼ arc formed in a height direction of the transparent member.

Both the method for forming an integrated component and the formed integrated component according to the above implementation of the disclosure have advantages as follows.

According to one aspect of the disclosure, the transparent member and the substrate member are bonded together through the adhesive, and the housing member is formed at the periphery of the transparent member and the substrate member which are bonded together, through the insert moulding technology. Since the transparent member does not need to be fixed with a tool through drilling, the intensity of the transparent member is not affected.

According to another aspect of the disclosure, the connection feature is formed on the edge of the transparent member, wherein the connection feature may be a concave portion formed through a cutting technology or formed integrally with the transparent member, and most preferably is a ¼-arc concave portion. Due to this connection feature, the contact surface between the transparent member and the housing member which is formed at the periphery of the transparent member through an insert moulding technology is not a flat surface as the related art, but a concave surface; thus, interlocking is formed between the housing member and the transparent member and sliding is not difficultly generated; therefore, the connection between the housing member and the transparent member is more tight and stable, and a seamless connection is realized.

According to another aspect of the disclosure, certain gap is retained between the mould and the transparent member, which can better protect the transparent member during the shaping process and avoid the damage of the transparent member.

### BRIEF DESCRIPTION OF THE DRAWINGS

The features and advantages of one or several implementations of the disclosure would become more understandable through the description of the drawings, in which,

FIG. 1 shows a diagram of a drilling connection way in the related art;

FIG. 2 shows a diagram of an absorption connection way in the related art;

FIG. 3A shows a diagram of a transparent member according to an implementation of the disclosure;

FIG. 3B shows a diagram of a transparent member with a connection feature according to an implementation of the disclosure;

FIG. 4A shows a diagram of the bonding between a transparent member and a substrate member according to an implementation of the disclosure;

FIG. 4B shows a diagram of the bonding between a transparent member and a substrate member according to another implementation of the disclosure;

FIG. 5A shows a diagram of an integrated component formed through an insert moulding technology according to an implementation of the disclosure; and

FIG. 5B shows a diagram of an integrated component formed through an insert moulding technology according to another implementation of the disclosure.

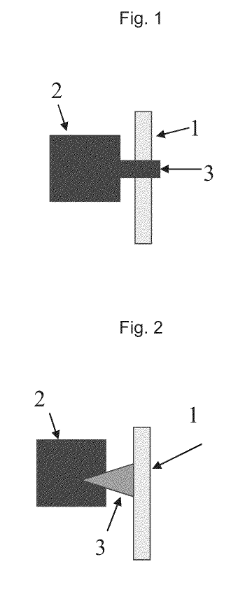

### DETAILED DESCRIPTION

The description provided below for preferred implementations is merely exemplary, and is not intended to limit the application or usage of the disclosure.

According to an implementation of the disclosure, in order to realize a tight and stable connection between a transparent member and a housing member, the disclosure provides a method for forming an integrated component, which includes the following steps: bonding the transparent member and a substrate member together through an adhesive; placing the transparent member and the substrate member which are bonded together in a mould; and forming the housing member at the periphery of the transparent member and the substrate member which are bonded together, through an insert moulding technology, so that the housing member and the transparent member are jointed together to form an integrated component.

The transparent member may be transparent materials such as glass and plastic. The substrate member may be a frame, an insert moulding label foil and so on. The housing member may be electronic device shells such as a cell phone shell, a tablet computer shell, a music player shell and the like. The housing member may be made of materials such as metal and plastic.

The insert moulding technology refers to a shaping method in which a thermoplastic or thermosetting material is injected into a mould after an insert of different materials prepared in advance is placed in this mould, and then the fused material and the insert are jointed and solidified to form an integrated product. Here, the insert generally refers to a metal material. In the application, it is not to inject materials such as thermoplastic material around a metal insert but to inject materials such as metal material around a transparent insert such as glass insert, through the insert moulding technology, so as to form a housing member enclosing the transparent insert such as glass insert. The fused material injected into the mould flows around the transparent insert such as glass insert, and is effectively bonded with the transparent insert such as glass insert after being solidified, to form a tight and stable connection.

Hereinafter, the implementation of the disclosure is described in detail by taking the transparent member being glass, the substrate member being a frame and the housing member being a cell phone shell for example.

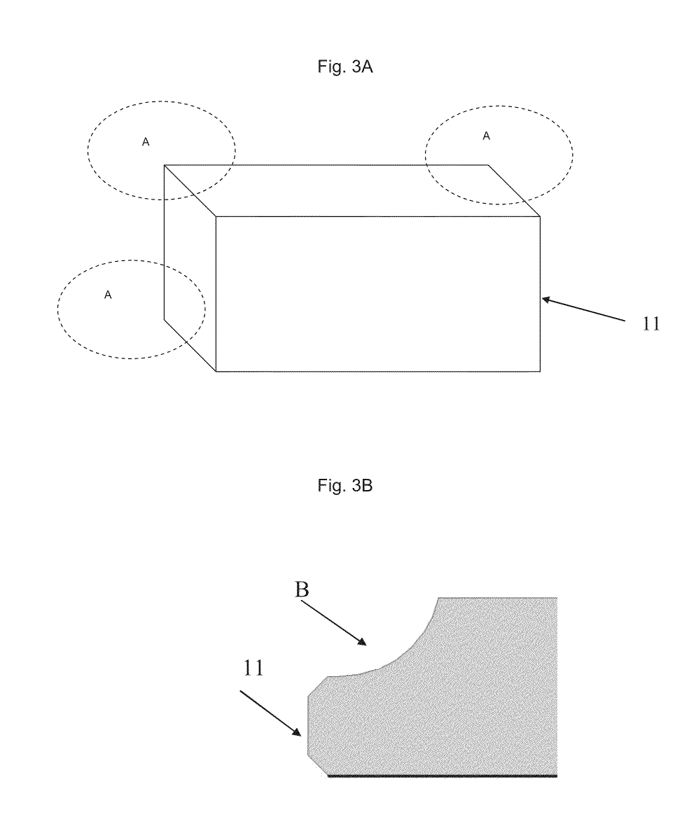

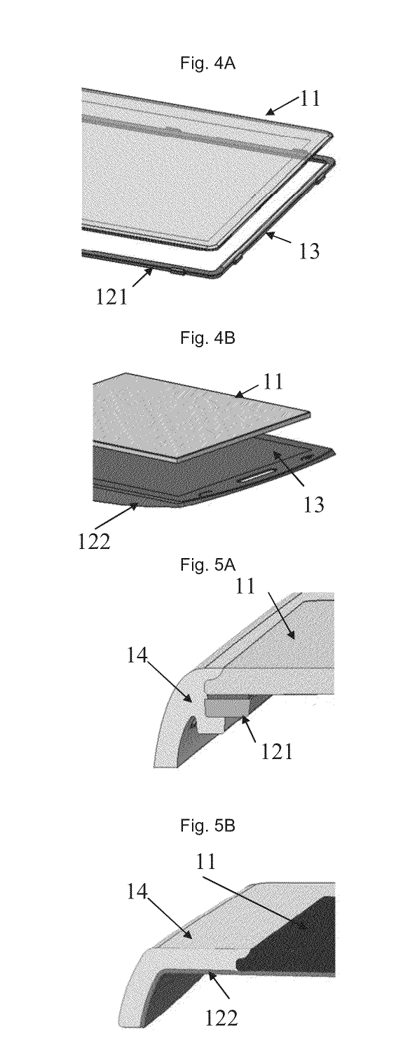

Refer to FIG. 3A, FIG. 4A and FIG. 5A, FIG. 3A shows glass 11; FIG. 4A shows a diagram of the glass 11 and a frame 121 bonded together through an adhesive 13; FIG. 5A shows an integrated component finally formed by the glass 11, the frame 121 and a cell phone A shell 14 through an insert moulding technology.

Specifically, in order to realize a tight and stable connection between the glass 11 and the cell phone A shell 14, first, the glass 11 is bonded with the frame 121 through the adhesive 13, as shown in FIG. 4A, wherein the adhesive 13 is coated on the outer edge of the glass 11 or on the inner edge of the frame 121, and then the glass 11 and the frame 121 are bonded together; second, the glass 11 and the frame 121 which are bonded together are placed into a mould, and a fused material is injected into the mould, after the fused material, the glass 11 and the frame 121 are jointed and solidified, the cell phone shell 14 is formed at the periphery; as shown in FIG. 5A, the cell phone shell 14 effectively grabs the glass 11 and the frame 121, and thus forms a tight and stable connection with the glass 11 and the frame 121. Here, the fused material used for forming the cell phone A shell may be metal, plastic and other materials. Those skilled in the art should understand that the fused material used for forming the cell phone shell may be any material that can be injection-moulded. Here, the frame 121 may be made of metal or plastic.

The substrate member may also be an insert moulding label foil 122. As shown in FIG. 4B, the glass 11 and the insert moulding label foil 122 are bonded together through the adhesive 13. FIG. 5B shows an integrated component finally formed by the glass 11, the insert moulding label foil 122 and the cell phone A shell 14 through the insert moulding technology.

Specifically, in order to realize a tight and stable connection between the glass 11 and the cell phone A shell 14, first, the glass 11 is bonded with the insert moulding label foil 122 through the adhesive 13, as shown in FIG. 4B, wherein the adhesive 13 is coated on the lower surface of the glass 11 or on the upper surface of the insert moulding label foil 122, and then the glass 11 and the insert moulding label foil 122 are bonded together; second, the glass 11 and the insert moulding label foil 122 which are bonded together are placed into a mould, and a fused material is injected into the mould, after the fused material, the glass 11 and the insert moulding label foil 122 are jointed and solidified, the cell phone A shell 14 is formed at the periphery; as shown in FIG. 5B, the cell phone A shell 14 effectively grabs the glass 11 and the insert moulding label foil 122, and thus forms a tight and stable connection with the glass 11 and the insert moulding label foil 122. Here, the fused material used for forming the cell phone A shell may be materials such as metal and plastic. Those skilled in the art should understand that the fused material used for forming the cell phone shell may be any material that can be injection-moulded.

According to the above implementation provided by the disclosure, the transparent member and the substrate member are bonded together first through the adhesive, and then a housing member is formed at the periphery of the transparent member and the substrate member which are bonded together, through an insert moulding technology. Since the transparent member does not need to be fixed with a tool through drilling, the intensity of the transparent member is not affected. Moreover, the solidified housing member formed at the periphery of the transparent member and the substrate member through the insert moulding technology effectively grabs the transparent member and the substrate member, and thus forms a tight and stable connection with the transparent member and the substrate member.

According to another implementation of the disclosure, in order to further enforce the tight and stable connection between the transparent member and the housing member, and to prevent the sliding between the transparent member and the housing member, the transparent member provided by the disclosure contains at least one connection feature. The connection feature may be a concave portion formed on the edge of the transparent member through a cutting technology or a concave portion located at the edge of the transparent member and integrally formed with this transparent member. Preferably, the concave portion is a ¼ arc. Those skilled in the art should understand that this concave portion may be of any other concave shapes, for example, right angle, fillet and the like. The connection feature may also be a tapered plane formed in the thickness direction of the transparent member. Those skilled in the art should understand that there may be a plurality of connection features, for example, the connection feature may be located at the upper or lower edge of one side of the transparent member only, or may be located at the upper and lower edges of one side of the transparent member, or may be located at the upper or lower edges of two sides of the transparent member, or may be located at the upper and lower edges of two sides of the transparent member, or may be located at the peripheral edge of the transparent member, for example, the upper edge, or the lower edge, or both upper and lower edges of the periphery.

The above implementation is illustrated below by taking the concave portion being a ¼ arc for example.

FIG. 3A shows a transparent member without a connection feature; FIG. 3B shows a transparent member with a connection feature; both FIG. 5A and FIG. 5B show an integrated component formed by a transparent member with a connection feature, a substrate member and a housing member, wherein the substrate member is the frame 121 in FIG. 5A, while the substrate member is the insert moulding label foil 122 in FIG. 5B.

As shown in FIG. 3A, the position marked by A is an area to form a connection feature, which is located at the edge of the transparent member 11; and the transparent member 11 with a connection feature B is formed through a cutting technology or an integration manner; as shown in FIG. 3B, the connection feature B is a ¼ arc.

The implementation of the transparent member with a connection feature and the implementation of the transparent member without a connection feature have the same steps, except that the structure is different. However, since the transparent member 11 has the connection feature B at the edge, during the process of the fused material flowing around the transparent member 11 and the substrate member 121, 122 which are bonded together and becoming solidification, the joint portion between the formed housing member 14 and the transparent member 11 forms a convex feature corresponding to the connection feature B; thus, the contact surface between the housing member 14 and the transparent member 11 is no loner a flat surface, but a curve surface determined by the shape of the connection feature B; therefore, the housing member 14 can grab the transparent member 11 more effectively, and forms with the transparent member 11 an interlocking and seamless connection through which sliding is difficulty generated, so as to further enforce the tight and stable connection between the housing member 14 and the transparent member 11.

In each method for forming an integrated component described above, optionally, certain gap is retained between the transparent member and the mould, so as to prevent the transparent member from damaging during the shaping process.

Therefore, according to each method for forming an integrated component described above, a tight and stable connection can be better realized between the housing member and the transparent member, sliding can be prevented between the housing member and the transparent member, an interlocking and seamless connection can be formed between the housing member and the transparent member, and the problem that the quality of the transparent member is affected due to the drilling on the transparent member can be avoided.

The disclosure also provides an integrated component, which includes: a transparent member, a substrate member and a housing member, wherein the transparent member and the substrate member are bonded together through an adhesive; the housing member is formed at the periphery of the transparent member and the substrate member which are bonded together, through an insert moulding technology, and is tightly jointed with the transparent member and the substrate member.

The transparent member may be transparent materials such as glass and plastic. The substrate member may be a frame, an insert moulding label foil and so on. The housing member may be electronic device shells such as a cell phone A shell, a tablet computer shell, a music player shell and the like. The housing member may be made of materials such as metal and plastic.

According to another implementation, the transparent member provided by the disclosure contains at least one connection feature. The connection feature may be a concave portion formed on the edge of the transparent member through a cutting technology or a concave portion located at the edge of the transparent member and integrally formed with this transparent member. Preferably, the concave portion formed by the cutting technology or integration manner is a ¼ arc. Those skilled in the art should understand that this concave portion may be of any other concave shapes, for example, right angle, fillet and the like. Those skilled in the art should understand that there may be a plurality of connection features, for example, the connection feature may be located at the upper or lower edge of one side of the transparent member only, or may be located at the upper and lower edges of one side of the transparent member, or may be located at the upper or lower edges of two sides of the transparent member, or may be located at the upper and lower edges of two sides of the transparent member, or may be located at the peripheral edge of the transparent member, for example, located at the upper edge, or the lower edge, or both upper and lower edges of the periphery.

The integrated component provided by the disclosure is formed by the method for forming an integrated component described above; therefore, the formed integrated component has the advantages of the above method for forming an integrated component too, and no further description is needed here.

Although various implementations of the disclosure have been described above in detail, it should be understood that the disclosure is not limited to the specific implementation provided and described above; those skilled in the art can implement other modifications and transformations without departing from the essence and scope of the disclosure. However, all these modifications and transformations are deemed to be included with the scope of the disclosure. Further, all members described above can be replaced by other technical equivalent members.

What is claimed is:

1. A method for forming an integrated component, comprising:
bonding a transparent member and a substrate member together through an adhesive;
placing the transparent member and the substrate member which are bonded together in a mould; and
forming a housing member at a periphery of the transparent member and the substrate member which are bonded together, through an insert moulding technology, so that the housing member and the transparent member are jointed together to form an integrated component.

2. The method according to claim 1, wherein the transparent member is glass.

3. The method according to claim 1, wherein the substrate member is a frame.

4. The method according to claim 1, wherein the substrate member is an insert moulding label foil.

5. The method according to claim 1, wherein at least one connection feature is located at an edge of the transparent member.

6. The method according to claim 5, wherein the connection feature is a concave portion formed on the edge of the transparent member through a cutting technology, or a concave portion located at the edge of the transparent member and integrally formed with the transparent member.

7. The method according to claim 6, wherein the concave portion is a ¼ arc formed in a height direction of the transparent member.

8. An integrated component, comprising:
a transparent member, a substrate member and a housing member, wherein
the transparent member and the substrate member are bonded together through an adhesive; the housing member is formed at a periphery of the transparent member and the substrate member which are bonded together, through an insert moulding technology, and is jointed with the transparent member and the substrate member.

9. The integrated component according to claim 8, wherein the transparent member is glass.

10. The integrated component according to claim 8, wherein the substrate member is a frame.

11. The integrated component according to claim 8, wherein the substrate member is an insert moulding label foil.

12. The integrated component according to claim 8, wherein at least one connection feature is located at an edge of the transparent member.

13. The integrated component according to claim 12, wherein the connection feature is a concave portion formed on the edge of the transparent member through a cutting technology, or a concave portion located at the edge of the transparent member and integrally formed with the transparent member.

14. The integrated component according to claim 13, wherein the concave portion is a ¼ arc formed in a height direction of the transparent member.
